(19) United States
(12) Patent Application Publication
(10) Pub. No.: US 2026/0074700 A1
(43) Pub. Date: Mar. 12, 2026

(54) SEMICONDUCTOR DEVICE, POWER SUPPLY SYSTEM, AND VEHICLE

(71) Applicant: ROHM Co., Ltd., Kyoto (JP)

(72) Inventor: Yuki Teramae, Kyoto (JP)

(73) Assignee: ROHM Co., Ltd., Kyoto (JP)

(21) Appl. No.: 19/313,865

(22) Filed: Aug. 29, 2025

(30) Foreign Application Priority Data
Sep. 6, 2024 (JP) 2024-154041

(51) Int. Cl. H03K 19/0185; H02M 3/158; H03K 5/135

(52) U.S. Cl. CPC H03K 19/018585; H02M 3/1584; H03K 5/135; H03K 19/01855

(57) ABSTRACT

A semiconductor device (1) includes: multiple channels of power supply circuits (51 to 57); a first input part (EN terminal) configured to input a first input signal; and a second input part (ADDEN1 terminal or I2C communication terminal) configured to input a second input signal, and is configured to be capable of setting allocation of the channels of the power supply circuits to each of an enable function using the first input signal and an additional enable function using the second input signal, first delay time information related to an elapsed time from when the first input signal indicating startup is input until the channel allocated to the enable function starts up, and second delay time information related to an elapsed time from when the second input signal indicating startup is input until the channel allocated to the additional enable function starts up.

### CROSS-REFERENCE TO RELATED APPLICATION

This application claims the priority benefit of Japanese application serial no. 2024-154041, filed on Sep. 6, 2024. The entirety of the above-mentioned patent application is hereby incorporated by reference herein and made a part of this specification.

### TECHNICAL FIELD

The disclosure relates to a semiconductor device.

### BACKGROUND ART

Conventionally, a PMIC (Power Management IC) that includes multiple channels of power supply circuits is known (for example, Patent Document 1).

### RELATED ART DOCUMENT

### Patent Document

[Patent Document 1] Japanese Patent Application Laid-Open No. 2021-93842 In a PMIC, the startup timing of each channel is determined according to user requirements. For example, a PMIC for in-vehicle SoC (System on a chip) requires various startup timing settings to implement control of all electronic components mounted in a vehicle.

### SUMMARY

A semiconductor device according to one aspect of the disclosure includes:
multiple channels of power supply circuits;
a first input part configured to input a first input signal; and
a second input part configured to input a second input signal, and
is configured to be capable of setting:
allocation of the channels of the power supply circuits to each of an enable function using the first input signal and an additional enable function using the second input signal,
first delay time information related to an elapsed time from when the first input signal indicating startup is input until the channel allocated to the enable function starts up, and
second delay time information related to an elapsed time from when the second input signal indicating startup is input until the channel allocated to the additional enable function starts up.

### BRIEF DESCRIPTION OF THE DRAWINGS

FIG. 1 is a block diagram showing the configuration of the semiconductor device according to an exemplary embodiment of the disclosure.

FIG. 2 is a plan view of the semiconductor device as viewed from above.

FIG. 3 is a diagram showing the register map for setting the delay time for determining the startup timing.

FIG. 4 is a diagram showing the register map for setting the enable/disable of the first additional enable function or the second additional enable function.

FIG. 5 is a timing chart showing an operation example of startup timing control in the semiconductor device.

FIG. 6 is a timing chart showing another operation example of startup timing control in the semiconductor device.

FIG. 7 is a diagram showing the register map for setting the delay time for determining the shutdown timing.

FIG. 8A is a diagram showing an example of the register map used for startup/shutdown timing control according to a modification example.

FIG. 8B is a diagram showing an example of the register map used for startup/shutdown timing control according to a modification example.

FIG. 9 is a diagram showing the configuration of the power supply system using the semiconductor device.

FIG. 10 is a diagram showing an example of another power supply system using the semiconductor device.

FIG. 11 is an external view showing an example of the vehicle.

### DESCRIPTION OF THE EMBODIMENTS

Hereinafter, exemplary embodiments of the disclosure will be described with reference to the drawings.

### 1. Configuration of PMIC

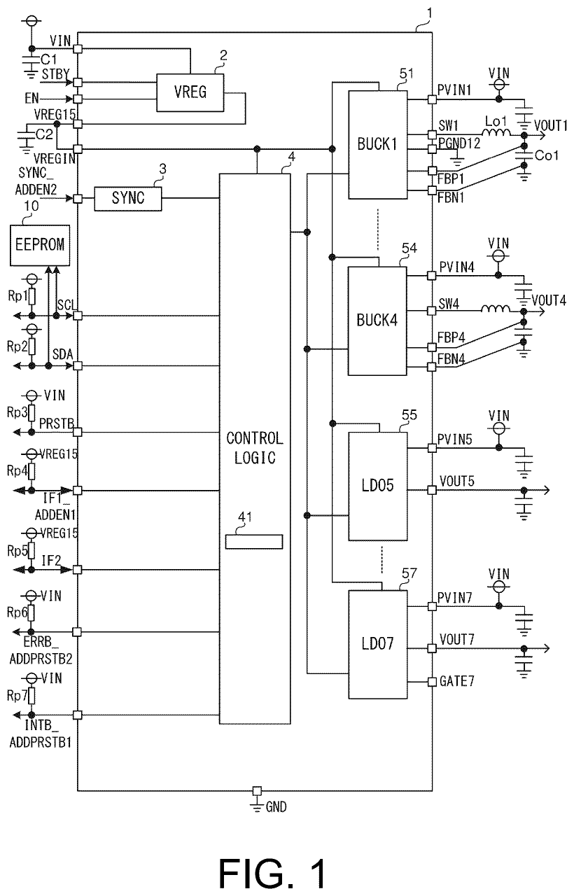

FIG. 1 is a block diagram showing the configuration of a semiconductor device 1 according to an exemplary embodiment of the disclosure. The semiconductor device 1 is configured as a PMIC. The semiconductor device 1 includes multiple channels of power supply circuits (BUCK1 to BUCK4, LDO5 to LDO7) as described later.

The semiconductor device 1 includes, as external terminals for establishing electrical connection with the outside, a VIN terminal, a STBY terminal, an EN terminal, a VREG15 terminal, a VREGIN terminal, a SYNC_ADDEN2 terminal, a SCL terminal, a SDA terminal, a PRSTB terminal, an IF1_ADDEN1 terminal, an IF2 terminal, an ERRB_ADDPRSTB2 terminal, an INTB_ADDPRSTB1 terminal, and a GND terminal.

The semiconductor device 1 includes, as internal configurations, an internal power supply circuit 2, a SYNC circuit 3, a controller (control logic) 4, buck power supply circuits 51 to 54, and LDO (Low Drop Out) circuits 55 to 57. The semiconductor device 1 has the foregoing internal configurations integrated on a single chip. That is, the semiconductor device 1 includes power supply circuits for a total of 7 channels, including buck power supply circuits for 4 channels and LDO circuits for 3 channels.

The semiconductor device 1 includes, as external terminals corresponding to the buck power supply circuits 51 to 54, PVIN1 to PVIN4 terminals, SW1 to SW4 terminals, FBP1 to FBP4 terminals, and FBN1 to FBN4 terminals. In addition, a PGND12 terminal as an external terminal is provided corresponding to the buck power supply circuits 51 and 52, and a PGND34 terminal as an external terminal is provided corresponding to the buck power supply circuits 53 and 54.

The semiconductor device 1 also includes, as external terminals corresponding to LDO55 to LDO5, PVIN5 to PVIN7 terminals, and VOUT5 to VOUT7 terminals. In addition, a GATE7 terminal as an external terminal is provided corresponding to LDO57.

An input voltage VIN is applied from the outside to the VIN terminal, and a capacitor C1, which is a bypass capacitor (pass capacitor), is externally connected between the VIN terminal and ground.

A standby signal STBY is input from the outside to the STBY terminal. An enable signal EN is input from the outside to the EN terminal.

The internal power supply circuit 2 generates an internal power supply voltage VREG15 based on the input voltage VIN. The internal power supply voltage VREG15 is a voltage of 1.5V, which is used as a power supply voltage inside the IC and is output from the VREG15 terminal. A capacitor C2, which is a pass capacitor, is connected between the VREG15 terminal and ground. The internal power supply voltage VREG15 is input to the VREGIN terminal and supplied to the controller 4 and each power supply circuit (51 to 57).

The SYNC_ADDEN2 terminal is a terminal commonly used for a SYNC (synchronization) function and a second additional enable function. The SYNC_ADDEN2 terminal allows the addition of the second additional enable function without increasing the number of terminals. In addition, the second additional enable function and a first additional enable function to be described later are functions added to the enable function of the enable signal EN. In a case of the SYNC function being enabled, an external clock signal is input to the SYNC_ADDEN2 terminal, and the switching cycles of the buck power supply circuits 51 to 54 are synchronized with the external clock signal. Further, in a case of the second additional enable function being enabled, an additional enable signal ADD_EN2 is input to the SYNC_ADDEN2 terminal. Whether to enable the SYNC function or the second additional enable function is set in a register 41 (included in the controller 4) in the semiconductor device 1.

The SCL terminal and the SDA terminal are provided for I2C (Inter-Integrated Circuit) communication. I2C is a type of serial communication standard. A clock signal SCL is transmitted and received between the SCL terminal and an external device, and a data signal SDA is transmitted and received between the SDA terminal and the external device. The external device includes an EEPROM (Electrically Erasable Programmable Read-Only Memory) 10. The SCL terminal and the SDA terminal are pulled up by pull-up resistors Rp1 and Rp2, respectively. The serial communication is not limited to I2C, and for example, SPI (Serial Peripheral Interface) or the like may also be used.

The PRSTB (power-on reset) terminal is a terminal for outputting a reset signal PRSTB and is pulled up by a pull-up resistor Rp3. The reset signal PRSTB is an open drain signal and indicates active (reset state) at low level.

The IF1_ADDEN1 terminal is a terminal commonly used for an IF (interface) function and the first additional enable function. The IF1_ADDEN1 terminal allows the addition of the first additional enable function without increasing the number of terminals. The IF function is a terminal for communication between the semiconductor device 1 and an external PMIC. In a case of the IF function being enabled, a clock for the communication is input and output to the IF1_ADDEN1 terminal. In addition, in a case of the first additional enable function being enabled, an additional enable signal ADD_EN1 is input to the IF1_ADDEN1 terminal. Whether to enable the IF function or the first additional enable function is set in the register 41. The IF1_ADDEN1 terminal is pulled up by a pull-up resistor Rp4.

The IF2 terminal is a terminal used for the IF function, and a clock is input and output. The IF2 terminal is pulled up by a pull-up resistor Rp5.

The ERRB_ADDPRSTB2 terminal is a terminal commonly used for an error notification function and a second additional power-on reset function. The ERRB_ADDPRSTB2 terminal allows the addition of the second additional power-on reset function without increasing the number of terminals. The second additional power-on reset function and a first additional power-on reset function to be described later are functions added to the power-on reset function that uses the reset signal PRSTB. In a case of the error notification function being enabled, an error signal is output from the ERRB_ADDPRSTB2 terminal. In addition, in a case of the second additional power-on reset function being enabled, an additional reset signal ADD_PRSTB2 is output from the ERRB_ADDPRSTB2 terminal. Whether to enable the error notification function or the second additional power-on reset function is set in the register 41. The ERRB_ADDPRSTB2 terminal is pulled up by a pull-up resistor Rp6. The ERRB_ADDPRSTB2 terminal is active at low level by open drain.

The INTB_ADDPRSTB1 terminal is a terminal commonly used for an interrupt function and the first additional power-on reset function. The INTB_ADDPRSTB1 terminal allows the addition of the first additional power-on reset function without increasing the number of terminals. In a case of the interrupt function being enabled, an interrupt signal is output from the INTB_ADDPRSTB1 terminal. In addition, in a case of the first additional power-on reset function being enabled, an additional reset signal ADD_PRSTB1 is output from the INTB_ADDPRSTB1 terminal. Whether to enable the interrupt function or the first additional power-on reset function is set in the register 41. The INTB_ADDPRSTB1 terminal is pulled up by a pull-up resistor Rp7. The INTB_ADDPRSTB1 terminal is active at low level by open drain.

Next, the buck power supply circuit will be described. Here, with the buck power supply circuit 51 described as a representative example, the buck power supply circuit 51 includes a half bridge including a high-side switch and a low-side switch (both not shown), and a control circuit (not shown) that performs drive control of the high-side switch and the low-side switch. The buck power supply circuit 51, an inductor Lo1, and an output capacitor Co1 constitute a DC/DC converter (switching regulator) that generates an output voltage VOUT1 by stepping down the input voltage VIN.

The input voltage VIN is input from the outside to the PVIN1 terminal. The ground potential is applied to the PGND12 terminal. Here, as an example, the high-side switch is configured with a P-channel type MOSFET, and the low-side switch is configured with an N-channel type MOSFET. The source of the high-side switch is connected to the PVIN terminal, the drain of the high-side switch is connected to the drain of the low-side switch, and the source of the low-side switch is connected to the PGND12 terminal. That is, the high-side switch and the low-side switch are connected between the PVIN terminal and the PGND12 terminal. The node where the drain of the high-side switch and the drain of the low-side switch are connected is connected to the SW1 terminal. One end of the inductor Lo1 is externally connected to the SW1 terminal. The other end of the inductor Lo1 is connected to one end of the output capacitor Co1. The other end of the output capacitor Co1 is connected to ground. One end of the output capacitor Co1 is connected to the FBP1 terminal, and the other end of the output capacitor Co1 is connected to the FBN1 terminal. The voltage between the FBP1 terminal and the FBN1 terminal is input to the buck power supply circuit 51 as a feedback voltage, and the output voltage VOUT1 is feedback-controlled by the above-mentioned control circuit to become a target voltage. The ground applied to the PGND12 terminal is shared by the buck power supply circuits 51 and 52, and the ground applied to the PGND34 terminal is shared by the buck power supply circuits 53 and 54.

Next, the LDO circuit will be described. Here, with the LDO circuit 55 described as a representative example, the LDO circuit 55 includes an output transistor and a control circuit (both not shown) that performs drive control of the output transistor. The LDO circuit 55 is a DC/DC converter (series regulator) that generates an output voltage VOUT5 by stepping down the input voltage VIN. The output transistor is configured with a P-channel type MOSFET.

The input voltage VIN is input from the outside to the PVIN5 terminal. The PVIN5 terminal is connected to the source of the output transistor. The VOUT5 terminal is connected to the drain of the output transistor. The output voltage VOUT5 generated at the VOUT5 terminal is fed back to the above-mentioned control circuit, and feedback control is performed so that the output voltage VOUT5 becomes a target voltage.

In a case of using an external output transistor for the LDO circuit 57, the GATE7 terminal is a terminal for driving the gate of the output transistor.

### Layout of External Terminal

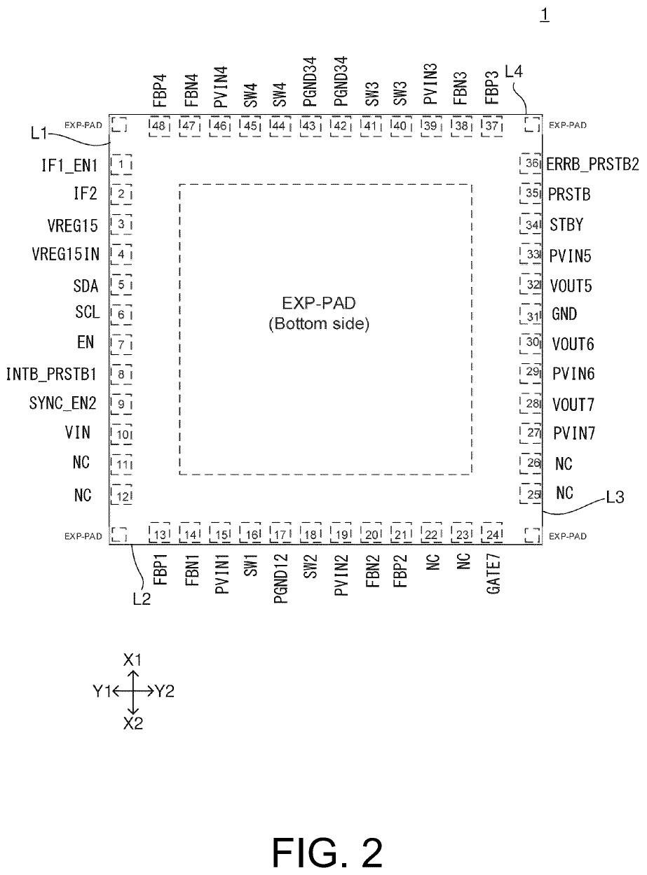

FIG. 2 shows a plan view of the semiconductor device 1 as viewed from above. The layout of external terminals (pin numbers 1 to 48) is shown in FIG. 2. In FIG. 2, the first direction X (up-down direction on the paper) is shown with the first direction one side X1 and the first direction other side X2, and the second direction Y (left-right direction on the paper) is shown with the second direction one side Y1 and the second direction other side Y2.

The semiconductor device 1 has a rectangular shape in plan view, and has a first edge L1, a second edge L2, a third edge L3, and a fourth edge L4. The first edge L1 and the third edge L3 extend in the first direction, and the second edge L2 and the fourth edge L4 extend in the second direction. The first edge L1 and the third edge L3 face each other in the second direction, and the second edge L2 and the fourth edge L4 face each other in the first direction. The first direction other side end of the first edge L1 is connected to the second direction one side end of the second edge L2. The second direction other side end of the second edge L2 is connected to the first direction other side end of the third edge L3. The first direction one side end of the third edge L3 is connected to the second direction other side end of the fourth edge L4. The second direction one side end of the fourth edge L4 is connected to the first direction one side end of the first edge L1.

Along the first edge L1, from the first direction one side in order, the IF1_EN1 terminal, IF2 terminal, VREG15 terminal, VREG15IN terminal, SDA terminal, SCL terminal, EN terminal, INT_BPRSTB1 terminal, SYNC_EN2 terminal, VIN terminal, NC (non-connection) terminal, and NC terminal are arranged.

Along the second edge L2, from the second direction one side in order, the FBP1 terminal, FBN1 terminal, PVIN1 terminal, SW1 terminal, PGND12 terminal, SW2 terminal, PVIN2 terminal, FBN2 terminal, FBP2 terminal, NC terminal, NC terminal, and GATE7 terminal are arranged.

Along the third edge L3, from the first direction other side in order, the NC terminal, NC terminal, PVIN7 terminal, VOUT7 terminal, PVIN6 terminal, VOUT6 terminal, GND terminal, VOUT5 terminal, PVIN5 terminal, STBY terminal, PRSTB terminal, and ERRB_PRSTB2 terminal are arranged.

Along the fourth edge L4, from the second direction other side in order, the FBP3 terminal, FBN3 terminal, PVIN3 terminal, SW3 terminal, SW3 terminal, PGND34 terminal, PGND34 terminal, SW4 terminal, SW4 terminal, PVIN4 terminal, FBN4 terminal, and FBP4 terminal are arranged.

In addition, heat dissipation pads (EXP-PAD) are arranged on the bottom surface of the semiconductor device 1 at four corners of the rectangle.

### Startup Timing Control

Next, the startup timing control in the semiconductor device 1 will be described. The startup timing control is the control of startup timing (timing when the output voltage begins to rise) in each of the buck power supply circuits 51 to 54 and the LDO circuits 55 to 57. The startup timing control is performed by the controller 4. A register map in the register 41 for settings related to the startup timing control will be described here.

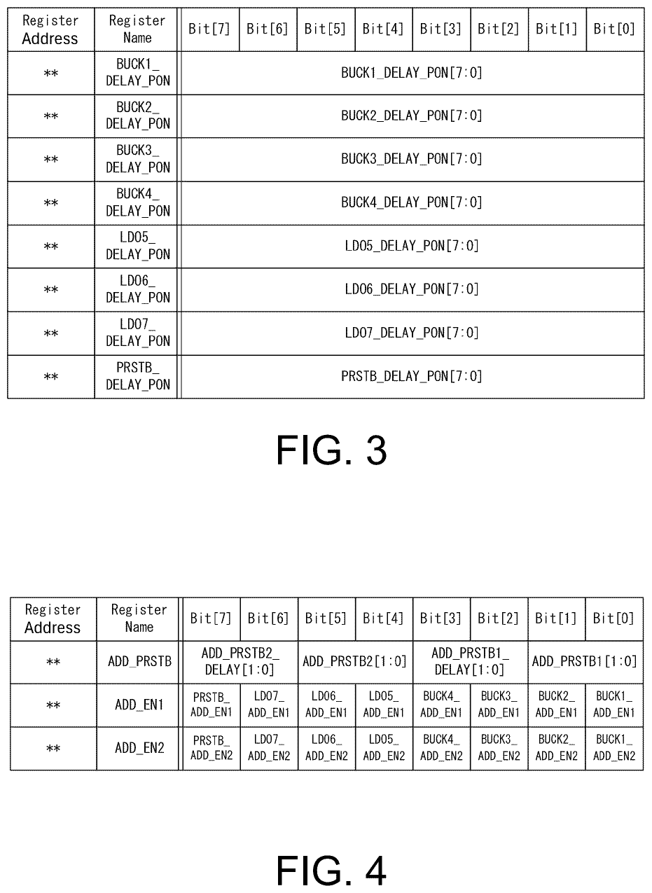

FIG. 3 is a diagram showing the register map for setting the delay time for determining the startup timing. In the register map shown in FIG. 3 and subsequent drawings, register address, data name (Register Name), and setting data are shown. The setting data is, as an example, 8-bit data (Bit[7] to Bit[0]). In addition, the delay time set here is a delay time from when any of the enable signal EN, the additional enable signal ADD_EN1, and the additional enable signal ADD_EN2 rises.

BUCK1_DELAY_PON to BUCK4_DELAY_PON are data for setting delay times for the buck power supply circuits 51 to 54, respectively. LDO5_DELAY_PON to LDO7_DELAY_PON are data for setting delay times for the LDO circuits 55 to 57, respectively. PRSTB_DELAY_PON is data for setting the delay time for the reset signal PRSTB.

FIG. 4 (lower two rows) is a diagram showing the register map for setting the enable/disable of the first additional enable function or the second additional enable function.

In FIG. 4, “ADD_EN1” shows data for setting the enable/disable of the first additional enable function. In ADD_EN1, BUCK1_ADD_EN1 to BUCK4_ADD_EN1, LDO5_ADD_EN1 to LDO7_ADD_EN1, and PRSTB_ADD_EN1 are stored one bit at a time in order from the lower bits. BUCK1_ADD_EN1 to BUCK4_ADD_EN1 are data for setting the enable/disable of the first additional enable function for each of the buck power supply circuits 51 to 54, respectively. LDO5_ADD_EN1 to LDO7_ADD_EN1 are data for setting the enable/disable of the first additional enable function for each of the LDO circuits 55 to 57, respectively. PRSTB_ADD_EN1 is data for setting the enable/disable of the first additional enable function for the reset signal PRSTB.

In a case where all bit values of BUCK1_ADD_EN1 to BUCK4_ADD_EN1, LDO5_ADD_EN1 to LDO7_ADD_EN1, and PRSTB_ADD_EN1 are set to “0”, the first additional enable function becomes disabled.

On the other hand, in a case where at least one bit value among BUCK1_ADD_EN1 to BUCK4_ADD_EN1, LDO5_ADD_EN1 to LDO7_ADD_EN1, and PRSTB_ADD_EN1 is set to “1”, the first additional enable function becomes enabled for those corresponding to the data set to “1” among the buck power supply circuits 51 to 54, the LDO circuits 55 to 57, and the reset signal PRSTB. When the first additional enable function is enabled, startup timing control of channel s based on the additional enable signal ADD_EN1 or reset release of the reset signal PRSTB is performed.

In FIG. 4, “ADD_EN2” shows data for setting the enable/disable of the second additional enable function. Since this data can be described by replacing “EN1” with “EN2” and replacing the first additional enable function with the second additional enable function in the case of “ADD_EN1” mentioned earlier, detailed description will be omitted.

In addition, for channels and reset signal PRSTB that are set to “0” in both “ADD_EN1” and “ADD_EN2”, the enable function becomes enabled, and startup timing control based on the enable signal EN is performed.

In this way, with the register map shown in FIG. 4, it is possible to set the channels that have the first additional enable function or the second additional enable function enabled among the multiple channels of power supply circuits.

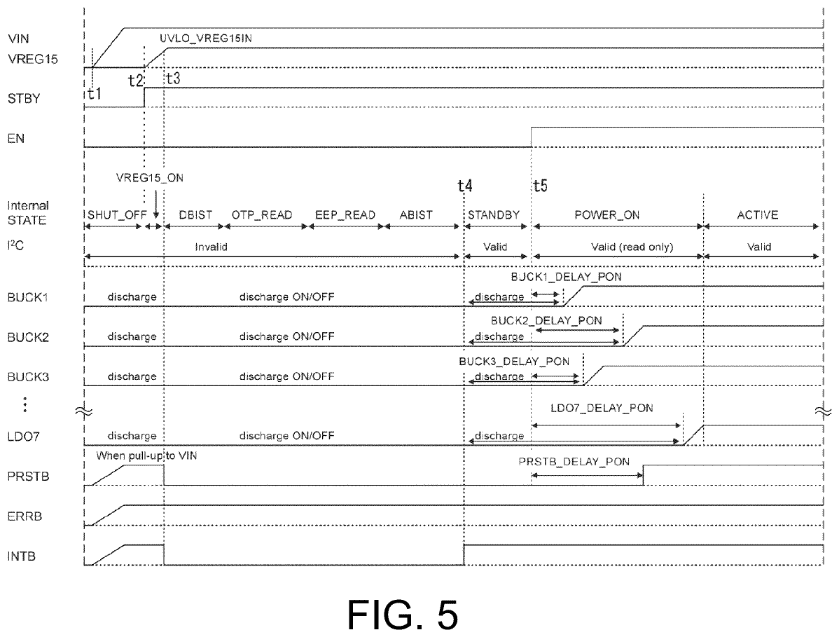

Next, an operation example of startup timing control will be described. FIG. 5 is a timing chart showing an operation example of startup timing control in the semiconductor device 1. FIG. 5 shows an operation example in a case where both the first additional enable function and the second additional enable function are set to be disabled, and only the enable function is set to be enabled. In FIG. 5, from the top in order, input voltage VIN, internal power supply voltage VREG15, standby signal STBY, enable signal EN, internal state, I2C communication state, output voltages corresponding to buck power supply circuits 51 to 54, output voltages corresponding to LDO circuits 55 to 57, reset signal PRSTB, error signal ERRB, and interrupt signal INTB are shown. Here, this is a case where the error notification function and the interrupt function are set to be enabled.

At timing t1, the input voltage VIN begins to rise. Then, at timing t2, when the standby signal STBY rises, the internal power supply circuit 2 is started up, and the internal power supply voltage VREG15 begins to rise. At timing t3, the UVLO (Under Voltage Lock Out) of the internal power supply voltage VREG15 is released. The internal state is in a shut-off state until timing t2, and is in a VREG15 on state from timing t2 to t3.

After timing t3, the internal state transitions in the order of digital BIST (built-in self-test) for the controller 4, OTP (One Time Programmable ROM) readout state, EEPROM readout state, and analog BIST for various protection circuits.

Subsequently, at timing t4, the internal state becomes standby state. Then, at timing t5, the enable signal EN rises. Each of the buck power supply circuits 51 to 54 and the LDO circuits 55 to 57 starts up at a timing, as the startup timing, when each delay time (BUCK1_DELAY_PON to BUCK4_DELAY_PON, and LDO5_DELAY_PON to LDO7_DELAY_PON) set by the register map shown in FIG. 3 has elapsed from timing t5. At the startup timing, each output voltage begins to rise.

In addition, the reset signal PRSTB is set to the reset state (low level) at timing t3, and transitions to the reset release state (high level) at a timing when the delay time (PRSTB_DELAY_PON) set by the register map shown in FIG. 3 has elapsed from the timing t5.

For the channels of power supply circuits or the reset signal PRSTB for which the enable function is enabled, the setting data of the register map shown in FIG. 3 is set, for example, as follows.
In a case of setting data=0×00, delay time=2 μs
In a case of setting data=0×01 to 0×80, delay time=128 μs to 16.384 ms (step=128 μs)
In a case of setting data=0×80 to 0×A0, delay time=16.384 ms to 24.576 ms (step=256 μs)
In a case of setting data=0×A0 to 0×C0, delay time=24.576 ms to 40.960 ms (step=512 μs)
In a case of setting data=0×C0 to 0×E0, delay time=40.960ms to 73.728 ms (step=1.024 ms)
In a case of setting data=0×E0 to 0×FF, delay time=73.728 ms to 137.216 ms (step=2.048 ms)

In this way, the step lengthens as the delay time increases. This enables the delay time to be set in a range as wide as possible while suppressing an increase in the number of bits of the setting data.

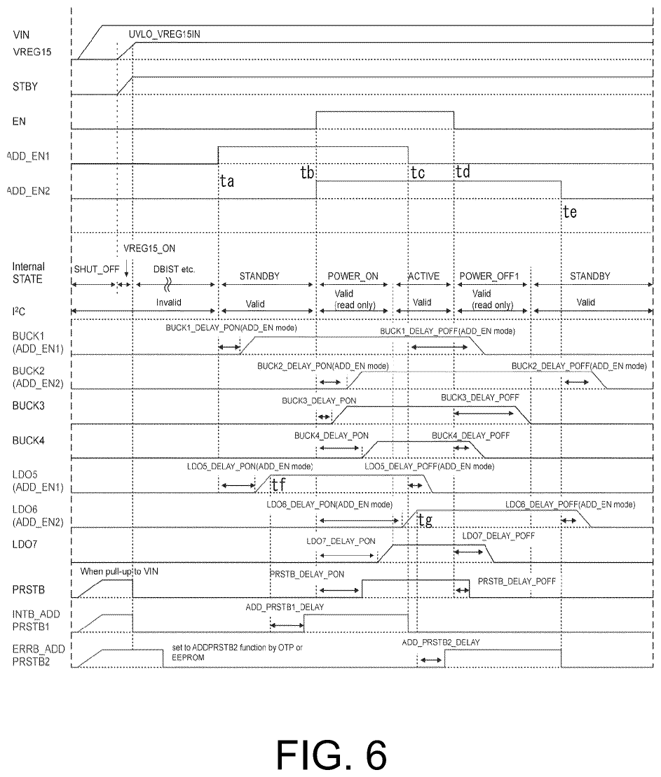

Next, FIG. 6 is a timing chart showing another operation example of startup timing control in the semiconductor device 1. FIG. 6 shows an operation example in a case where both the first additional enable function and the second additional enable function are set to be enabled. Specifically, the buck power supply circuit 51 and the LDO circuit 55 have the first additional enable function enabled, and the buck power supply circuit 52 and the LDO circuit 56 have the second additional enable function enabled. That is, in the register map of FIG. 4, in “ADD_EN1”, BUCK1_ADD_EN1 and LDO5_ADD_EN1 are set to “1”, and the others are set to “0”; and in “ADD_EN2”, BUCK2_ADD_EN2 and LDO6_ADD_EN2 are set to “1”, and the others are set to “0”. In this case, the enable function is enabled for the buck power supply circuits 53 and 54 and the LDO circuit 57.

Compared to FIG. 5, in FIG. 6, the additional enable signals ADD_EN1 and ADD_EN2 are shown between the enable signal EN and the internal state. The INTB_ADDPRSTB1 and ERRB_ADDPRSTB2 at the bottom of FIG. 6 will be described later.

Since the first additional enable function is enabled for the buck power supply circuit 51 and the LDO circuit 55, each of the buck power supply circuit 51 and the LDO circuit 55 starts up at a timing, as the startup timing, when each delay time (BUCK1_DELAY_PON and LDO5_DELAY_PON) set by the register map shown in FIG. 3 has elapsed from timing ta at which the additional enable signal ADD_EN1 rises.

Since the second additional enable function is enabled for the buck power supply circuit 52 and the LDO circuit 56, each of the buck power supply circuit 52 and the LDO circuit 56 starts up at a timing, as the startup timing, when each delay time (BUCK2_DELAY_PON and LDO6_DELAY_PON) set by the register map shown in FIG. 3 has elapsed from timing tb at which the additional enable signal ADD_EN2 rises.

For the channels of power supply circuits or the reset signal PRSTB for which the first additional enable function or the second additional enable function is enabled, the setting data of the register map shown in FIG. 3 is set, for example, as follows.

The upper 4 bits (Bit[7] to Bit[4]) are ignored,

In a case of setting data=0×0, delay time=2 μs

In a case of setting data=0×1 to 0×F, delay time=1.024 ms to 15.360 ms (step=1.024 ms)

The reason for making the setting data of the register map shown in FIG. 3 different in a case of enabling the enable function as described above is to avoid an increase in circuit area. However, if there is no constraint on the circuit area, the setting data may be the same.

In addition, since the enable function is enabled for the buck power supply circuits 53 and 54 and the LDO circuit 57, each of the buck power supply circuits 53 and 54 and the LDO circuit 57 starts up at a timing, as the startup timing, when each delay time (BUCK3_DELAY_PON, BUCK4_DELAY_PON and LDO7_DELAY_PON) set by the register map shown in FIG. 3 has elapsed from timing tb at which the enable signal EN rises.

Further, since the enable function is enabled for the reset signal PRSTB, the reset signal PRSTB transitions to the reset release state at a timing, as the startup timing, when the delay time (PRSTB_DELAY_PON) set by the register map shown in FIG. 3 has elapsed from timing tb at which the enable signal EN rises.

If the additional enable function is not provided in the semiconductor device 1 and only the enable function is provided, the startup timing would be set within the range after the delay time set by the register has elapsed from the rise of the enable signal EN. However, since this embodiment has the first and second additional enable functions, the setting range of the startup timing can be expanded. For example, with only the enable function, the latest controllable startup timing is the timing when the maximum delay time that can be set by the register has elapsed from the rise of the enable signal EN. By providing the additional enable function, however, it becomes possible to set a timing later than that startup timing as the startup timing.

### Shutdown Timing Control

In addition, the semiconductor device 1 according to this embodiment also has a function to control the timing of shutdown, not just startup. The shutdown timing control is performed by the controller 4.

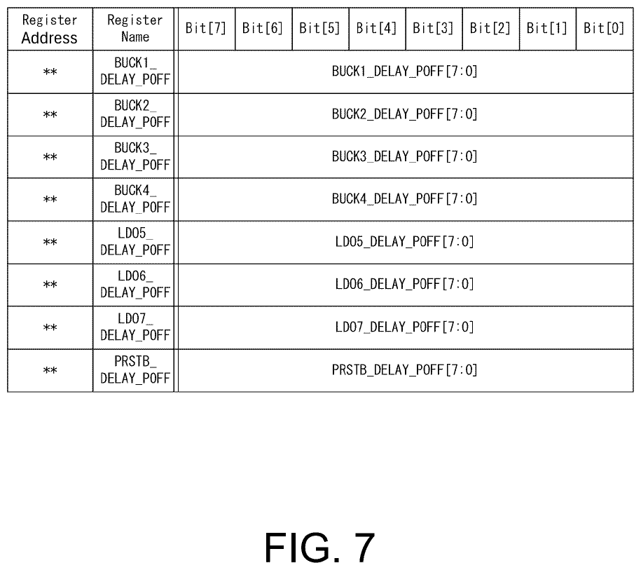

FIG. 7 is a diagram showing the register map for setting the delay time for determining shutdown timing. BUCK1_DELAY_POFF to BUCK4_DELAY_POFF are data for setting the delay time for each of the buck power supply circuits 51 to 54, respectively. LDO5_DELAY_POFF to LDO7_DELAY_POFF are data for setting the delay time for each of the LDO circuits 55 to 57, respectively. PRSTB_DELAY_POFF is data for setting the delay time for the reset signal PRSTB.

The shutdown timing control will be described using FIG. 6 as an example. In FIG. 6, as mentioned earlier, the first additional enable function is enabled for the buck power supply circuit 51 and the LDO circuit 55, the second additional enable function is enabled for the buck power supply circuit 52 and the LDO circuit 56, and the enable function is enabled for the buck power supply circuits 53 and 54 and the LDO circuit 57.

Therefore, as shown in FIG. 6, for the buck power supply circuit 51 and the LDO circuit 55, a timing when each delay time (BUCK1_DELAY_POFF and LDO5_DELAY_POFF) set by the register map shown in FIG. 7 has elapsed from timing tc at which the additional enable signal EN1 falls is set as the shutdown timing, at which the buck power supply circuit 51 and the LDO circuit 55 respectively shut down. The shutdown timing is a timing when the output voltage begins to fall.

Further, for the buck power supply circuit 52 and the LDO circuit 56, a timing when each delay time (BUCK2_DELAY_POFF and LDO6_DELAY_POFF) set by the register map shown in FIG. 7 has elapsed from timing te at which the additional enable signal EN2 falls is set as the shutdown timing, at which the buck power supply circuit 52 and the LDO circuit 56 respectively shut down.

Additionally, for the buck power supply circuits 53 and 54 and the LDO circuit 57, a timing when each delay time (BUCK3_DELAY_POFF, BUCK4_DELAY_POFF and LDO7_DELAY_POFF) set by the register map shown in FIG. 7 has elapsed from timing td at which the enable signal EN falls is set as the shutdown timing, at which the buck power supply circuits 53 and 54 and the LDO circuit 57 respectively shut down.

Furthermore, for the reset signal PRSTB, the reset signal PRSTB transitions to the reset state (low level) at a timing when the delay time (PRSTB_DELAY_POFF) set by the register map shown in FIG. 7 has elapsed from timing td at which the enable signal EN falls.

The values of delay times set by the register map shown in FIG. 7 also change according to whether the enable function or the additional enable function is enabled, similar to the register map (for startup) shown in FIG. 3 as described earlier. The setting values may be the same as or different from the values for startup.

### Additional Power-On Reset Function

Next, the additional power-on reset function will be described. In the register map shown in FIG. 4, “ADD_PRSTB” indicates the setting data for the additional power-on reset function. ADD_PRSTB1, which is stored in the first bit and second bit from the lower bit, is data for setting the enable/disable of the first additional power-on reset function. Specifically, for example,
in a case of ADD_PRSTB1=00, the first additional power-on reset function is disabled, that is, the interrupt function is enabled.

In a case of ADD_PRSTB1=10, the first additional power-on reset function is enabled for the additional enable signal EN1, and
in a case of ADD_PRSTB1=11, the first additional power-on reset function is enabled for the additional enable signal EN2.

ADD_PRSTB1_DELAY, which is stored in the third bit and fourth bit from the lower bit, is data for setting the delay time for the first additional power-on reset function. In a case where the first additional power-on reset function is enabled for the additional enable signal EN1, the additional reset signal ADD_PRSTB1 transitions to the reset release state (high level) at a timing when the delay time set by ADD_PRSTB1_DELAY has elapsed from the startup completion of the latest started up channel among the channels for which the first additional enable function is enabled. In a case where the first additional power-on reset function is enabled for the additional enable signal EN2, the additional reset signal ADD_PRSTB1 transitions to the reset release state at a timing when the delay time set by ADD_PRSTB1_DELAY has elapsed from the startup completion of the latest started up channel among the channels for which the second additional enable function is enabled.

ADD_PRSTB2, which is stored in the fifth bit and sixth bit from the lower bit, is data for setting the enable/disable of the second additional power-on reset function. Specifically, for example,
in a case of ADD_PRSTB2=00, the second additional power-on reset function is disabled, that is, the error notification function is enabled.

In a case of ADD_PRSTB2=10, the second additional power-on reset function is enabled for the additional enable signal EN1, and
in a case of ADD_PRSTB2=11, the second additional power-on reset function is enabled for the additional enable signal EN2.

ADD_PRSTB2_DELAY, which is stored in the seventh bit and eighth bit from the lower bit, is data for setting the delay time for the second additional power-on reset function. In a case where the second additional power-on reset function is enabled for the additional enable signal EN1, the additional reset signal ADD_PRSTB2 transitions to the reset release state at a timing when the delay time set by ADD_PRSTB2_DELAY has elapsed from the startup completion of the latest started up channel among the channels for which the first additional enable function is enabled. In a case where the second additional power-on reset function is enabled for the additional enable signal EN2, the additional reset signal ADD_PRSTB2 transitions to the reset release state at a timing when the delay time set by ADD_PRSTB2_DELAY has elapsed from the startup completion of the latest started up channel among the channels for which the second additional enable function is enabled.

ADD_PRSTB1_DELAY and ADD_PRSTB2_DELAY are set, for example, as follows.
In a case of ADD_PRSTB1_DELAY or ADD_PRSTB2_DELAY=00, delay time=2 μs
In a case of ADD_PRSTB1_DELAY or ADD_PRSTB2_DELAY=01, delay time=1.211 ms
In a case of ADD_PRSTB1_DELAY or ADD_PRSTB2_DELAY=10, delay time=4.845 ms
In a case of ADD_PRSTB1_DELAY or ADD_PRSTB2_DELAY=11, delay time=9.690 ms

Referring to the example in FIG. 6, since the first additional power-on reset function is enabled for the additional enable signal EN1, the additional reset signal ADD_PRSTB1 transitions to the reset release state at a timing when the delay time set by ADD_PRSTB1_DELAY has elapsed from timing (startup completion timing) tf at which the output voltage of the later started up one of the buck power supply circuit 51 and the LDO circuit 55, for which the first additional enable function is enabled, rises to a steady value.

In addition, since the second additional power-on reset function is enabled for the additional enable signal EN2, the additional reset signal ADD_PRSTB2 transitions to the reset release state at a timing when the delay time set by ADD_PRSTB2_DELAY has elapsed from timing (startup completion timing) tg at which the output voltage of the later started up one of the buck power supply circuit 52 and the LDO circuit 56, for which the second additional enable function is enabled, rises to a steady value.

With such additional power-on reset functions, it is possible to generate a reset signal in accordance with the additional enable function.

### Modification Example

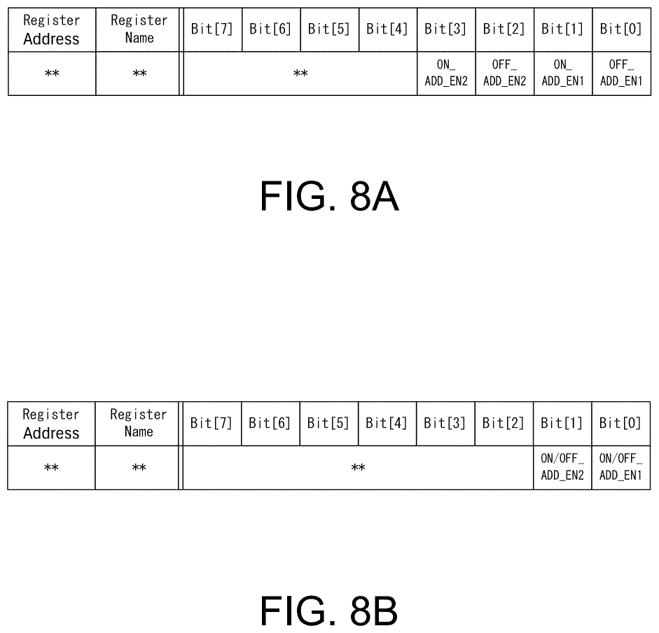

In a case where the additional enable signal as described above cannot be used, startup/shutdown timing control according to the following modification example may be implemented. FIG. 8A is a diagram showing an example of the register map used for startup/shutdown timing control according to a modification example. In the modification example, the register maps shown in FIG. 3 and FIG. 7 described above and the register map shown in FIG. 4 are also used.

In the register map shown in FIG. 8A, ON_ADD_EN1, OFF_ADD_EN1, ON_ADD_EN2, and OFF_ADD_EN2, each being 1-bit data, are stored.

When “1” is written to ON_ADD_EN1 via I2C communication, for channels for which the first additional enable function is enabled by “ADD_EN1” in the register map shown in FIG. 4, the power supply circuit is started up at a timing at which the delay time set by the register map shown in FIG. 3 has elapsed from when ON_ADD_EN1 is written.

When “1” is written to OFF_ADD_EN1 via I2C communication, for channels for which the first additional enable function is enabled by “ADD_EN1” in the register map shown in FIG. 4, the power supply circuit is shut down at a timing at which the delay time set by the register map shown in FIG. 7 has elapsed from when OFF_ADD_EN1 is written.

When “1” is written to ON_ADD_EN2 via I2C communication, for channels for which the second additional enable function is enabled by “ADD_EN2” in the register map shown in FIG. 4, the power supply circuit is started up at a timing at which the delay time set by the register map shown in FIG. 3 has elapsed from when ON_ADD_EN2 is written.

When “1” is written to OFF_ADD_EN2 via I2C communication, for channels for which the second additional enable function is enabled by “ADD_EN2” in the register map shown in FIG. 4, the power supply circuit is shut down at a timing at which the delay time set by the register map shown in FIG. 7 has elapsed from when OFF_ADD_EN2 is written.

Further, in a modification example, the register map shown in FIG. 8B may be used. Here, ON/OFF_ADD_EN1 and ON/OFF_ADD_EN2, each being 1-bit data, are stored.

When “1” is written to ON/OFF_ADD_EN1 via I2C communication, for channels for which the first additional enable function is enabled by “ADD_EN1” in the register map shown in FIG. 4, the power supply circuit is started up at a timing at which the delay time set by the register map shown in FIG. 3 has elapsed from when ON/OFF_ADD_EN1 is written.

When “0” is written to ON/OFF_ADD_EN1 via I2C communication, overwriting “1”, for channels for which the first additional enable function is enabled by “ADD_EN1” in the register map shown in FIG. 4, the power supply circuit is shut down at a timing at which the delay time set by the register map shown in FIG. 7 has elapsed from when ON/OFF_ADD_EN1 is written.

When “1” is written to ON/OFF_ADD_EN2 via I2C communication, for channels for which the second additional enable function is enabled by “ADD_EN2” in the register map shown in FIG. 4, the power supply circuit is started up at a timing at which the delay time set by the register map shown in FIG. 3 has elapsed from when ON/OFF_ADD_EN2 is written.

When “0” is written to ON/OFF_ADD_EN2 via I2C communication, overwriting “1”, for channels for which the second additional enable function is enabled by “ADD_EN2” in the register map shown in FIG. 4, the power supply circuit is shut down at a timing at which the delay time set by the register map shown in FIG. 7 has elapsed from when ON/OFF_ADD_EN2 is written.

In this way, in this modification example, startup/shutdown timing control can be performed using register writing via I2C communication as a trigger, instead of using the additional enable signal.

### Power Supply System

Next, a configuration example of a power supply system (also called a power tree) using the semiconductor device 1 according to the embodiment of the disclosure as described above will be described.

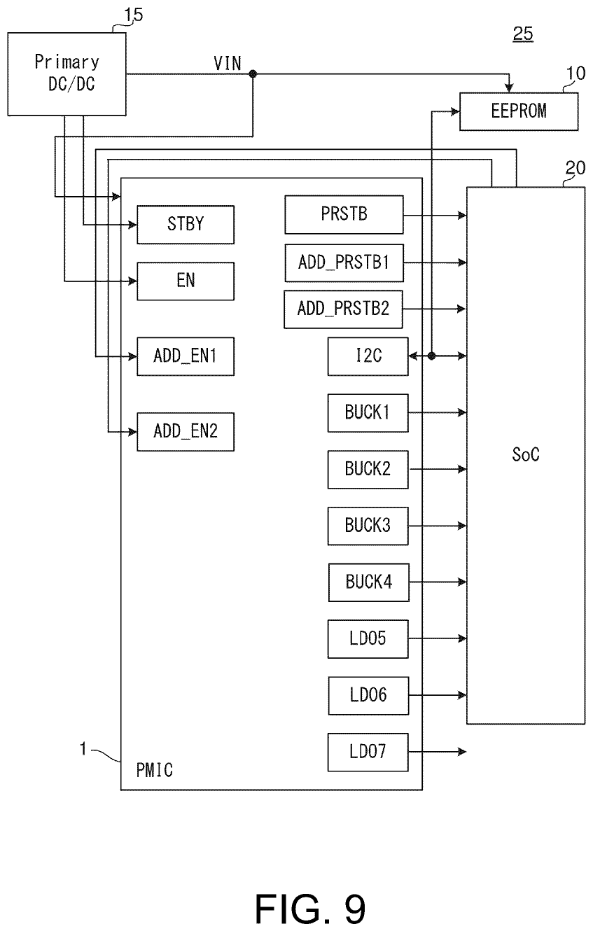

FIG. 9 is a diagram showing the configuration of a power supply system 25 using the semiconductor device 1. The power supply system 25 includes the semiconductor device 1, an EEPROM 10, a primary DC/DC converter 15, and a SoC 20.

The primary DC/DC converter 15 supplies an input voltage VIN generated through DC/DC conversion to the semiconductor device 1 and the EEPROM 10. In addition, a standby signal STBY and an enable signal EN are input from the primary DC/DC converter 15 to the semiconductor device 1. The output voltages generated by the buck power supply circuits 51 to 54 (BUCK1 to BUCK4) and the LDO circuits 55 and 56 (LDO5, LDO6) in the semiconductor device 1 are supplied to the SoC 20.

Additional enable signals ADD_EN1 and ADD_EN2 are input from the SoC 20 to the semiconductor device 1. This enables startup/shutdown timing control to be performed according to the timing generated on the SoC 20 side. In addition, a reset signal PRSTB and additional reset signals ADD_PRSTB1 and ADD_PRSTB2 are input from the semiconductor device 1 to the SoC 20. The additional reset signals ADD_PRSTB1 and ADD_PRSTB2 can notify the SoC 20 of the startup completion of channels for which the first and second additional enable functions are enabled.

For each of the pair of additional enable signal ADD_EN1 and additional reset signal ADD_PRSTB1, and the pair of additional enable signal ADD_EN2 and additional reset signal ADD_PRSTB2, an individual SoC may be provided.

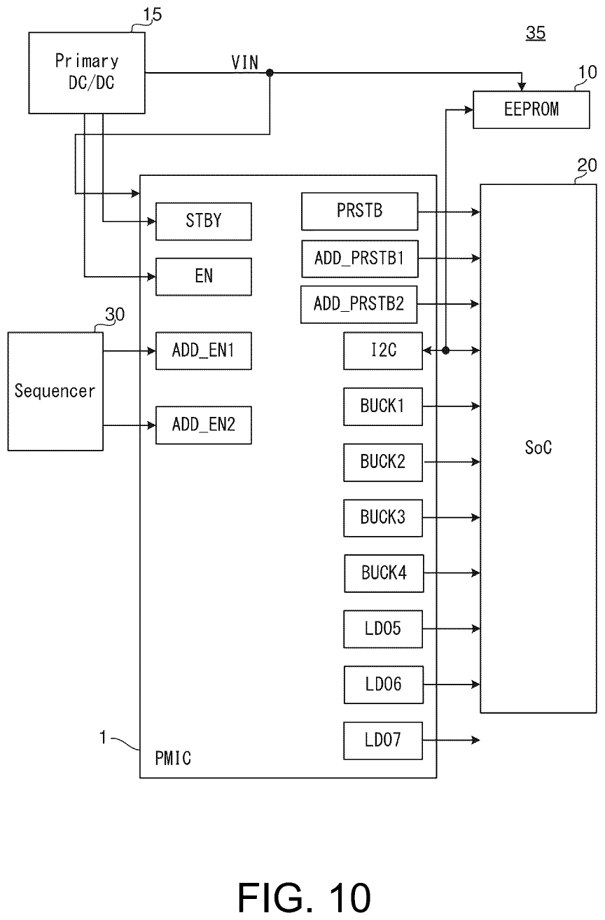

FIG. 10 is a diagram showing an example of another power supply system using the semiconductor device 1. In a power supply system 35 shown in FIG. 10, a sequencer 30 is provided as a difference from the previously described power supply system 25 shown in FIG. 9. Additional enable signals ADD_EN1 and ADD_EN2 are input from the sequencer 30 to the semiconductor device 1. This enables startup/shutdown timing control to be performed according to the timing instructed by the sequencer 30.

Nevertheless, the configuration of the power supply system using the semiconductor device 1 is not limited to the above, and can take various forms. For example, the additional enable signal may be input from the primary DC/DC converter 15 to the semiconductor device 1, or may be input from a microcontroller to the semiconductor device 1. Also, the additional reset signal may be input from the semiconductor device 1 to a microcontroller.

Furthermore, in a case of not using the additional enable signal, startup/shutdown timing control can be performed as in the modification example described earlier, for example, through I2C communication between the SoC and the semiconductor device 1.

### Vehicle

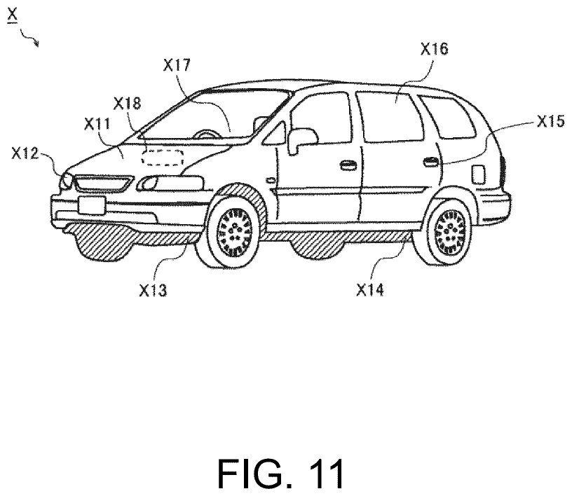

FIG. 11 is an external view showing a configuration example of a vehicle X. The vehicle X of this configuration example is equipped with various electronic devices X11 to X18 that operate by receiving power supply from a battery (not shown). It should be noted that the mounting positions of the electronic devices X11 to X18 in FIG. 11 may differ from the actual positions for the convenience of illustration.

The electronic device X11 is an engine control unit that performs control related to the engine (injection control, electronic throttle control, idling control, oxygen sensor heater control, and auto cruise control).

The electronic device X12 is a lamp control unit that performs on/off control of HID [high intensity discharged lamp], DRL [daytime running lamp], etc.

The electronic device X13 is a transmission control unit that performs control related to the transmission.

The electronic device X14 is a body control unit that performs control related to the motion of the vehicle X (ABS [anti-lock brake system] control, EPS [electric power steering] control, electronic suspension control, etc.).

The electronic device X15 is a security control unit that performs drive control of door lock, security alarm, etc.

The electronic device X16 is an electronic device incorporated into the vehicle X at the factory shipment stage as standard equipment or manufacturer options, such as wiper, power door mirror, power window, damper (shock absorber), power sunroof, power seat, etc.

The electronic device X17 is an electronic device optionally attached to the vehicle X as a user option, such as in-vehicle A/V [audio/visual] equipment, car navigation system, ETC [electronic toll collection system], etc.

The electronic device X18 is an electronic device including high-voltage-resistant motors such as in-vehicle blower, oil pump, water pump, battery cooling fan, etc.

The power supply system including the semiconductor device 1 described above may be applied to any of the electronic devices X11 to X18.

### Others

Various technical features disclosed in this specification may be modified in various ways within the scope that does not deviate from the spirit of the technical creation, in addition to the above embodiments. That is, the above embodiments should be considered as illustrative in all aspects and not restrictive, and the technical scope of the disclosure is not limited to the above embodiments, but should be understood to include all modifications belonging to the equivalent meaning and scope of the claims.

### Appendix

As described above, a semiconductor device (1) according to one aspect of the disclosure includes:
multiple channels of power supply circuits (51 to 57);
a first input part (EN terminal) configured to input a first input signal; and
a second input part (ADDEN1 terminal or I2C communication terminal) configured to input a second input signal, in which
the semiconductor device is configured to be capable of setting:
allocation of the channels of the power supply circuits to each of an enable function using the first input signal and an additional enable function using the second input signal,
first delay time information related to an elapsed time from when the first input signal indicating startup is input until the channel allocated to the enable function starts up, and
second delay time information related to an elapsed time from when the second input signal indicating startup is input until the channel allocated to the additional enable function starts up (first configuration).

According to such a configuration, the flexibility in setting the startup timing of the power supply circuit can be enhanced.

Further, in the above first configuration, the first input signal is an enable signal that takes a high level or a low level, and
the channel allocated to the enable function may start up at a timing when an elapsed time indicated by the first delay time information has elapsed after the enable signal is switched to a level indicating startup (second configuration).

Further, in the above second configuration, the second input signal is an additional enable signal that takes a high level or a low level, and
the channel allocated to the additional enable function may start up at a timing when an elapsed time indicated by the second delay time information has elapsed after the additional enable signal is switched to a level indicating startup (third configuration).

Further, in the above third configuration, the additional enable signal may be inputtable to the first input part for a different function from the enable function and the additional enable function (fourth configuration).

Further, in the above fourth configuration, the different function may be a synchronization function for synchronizing a switching frequency of the power supply circuit with an external clock, or a communication function with another semiconductor device (fifth configuration).

Further, the above second configuration further includes a register, in which
the second input signal is a serial communication signal, and
in a case where information indicating startup is written in the register by the serial communication signal, the channel allocated to the additional enable function may start up at a timing when an elapsed time indicated by the second delay time information has elapsed after the information is written (sixth configuration).

Further, in any of the above first to sixth configurations, the first delay time information may have a step that lengthens as a setting time increases (seventh configuration).

Further, any of the above first to seventh configurations may be configured to be capable of setting:
third delay time information related to an elapsed time from when the first input signal indicating shutdown is input until the channel allocated to the enable function shuts down, and
fourth delay time information related to an elapsed time from when the second input signal indicating shutdown is input until the channel allocated to the additional enable function shuts down (eighth configuration).

Further, any of the above first to eighth configurations further includes a first output part configured to output a reset signal, in which
the semiconductor device may be configured to be capable of setting:
allocation of the reset signal to the additional enable function, and
fifth delay time information related to an elapsed time from when the second input signal indicating startup is input until the reset signal transitions to a reset release state (ninth configuration).

Further, the above ninth configuration further includes a second output part configured to output an additional reset signal, in which
the semiconductor device may be configured to be capable of setting:
allocation of the additional reset signal to the additional enable function, and
sixth delay time information related to an elapsed time from when the channel that starts up last among the channels allocated to the additional enable function completes startup until the additional reset signal transitions to a reset release state (tenth configuration).

Further, in the above tenth configuration, the additional reset signal may be configured to be outputtable from the second output part for a different function from a power-on reset function (eleventh configuration).

In addition, a power supply system (25) according to one aspect of the disclosure includes: the semiconductor device of any of the above first to eleventh configurations; and an external device (20) configured to be supplied with an output voltage generated based on the power supply circuit (twelfth configuration).

Further, in the above twelfth configuration, the second input signal may be configured to be inputtable from the external device to the semiconductor device (thirteenth configuration).

Further, in the above thirteenth configuration, the external device may be configured as a SoC (fourteenth configuration).

Further, any of the above twelfth to fourteenth configurations further includes a sequencer (30), in which the second input signal may be configured to be inputtable from the sequencer to the semiconductor device (fifteenth configuration).

In addition, a vehicle (X) according to one aspect of the disclosure includes the power supply system of any of the above twelfth to fifteenth configurations (sixteenth configuration).

Further, the communication system of the above tenth configuration may be configured to be mountable on a vehicle (eleventh configuration).

### INDUSTRIAL APPLICABILITY

The disclosure can be utilized, for example, in power supply systems for various applications.

What is claimed is:

1. A semiconductor device, comprising:
multiple channels of power supply circuits;
a first input part configured to input a first input signal; and
a second input part configured to input a second input signal, wherein the semiconductor device is configured to be capable of setting:
allocation of the channels of the power supply circuits to each of an enable function using the first input signal and an additional enable function using the second input signal,
first delay time information related to an elapsed time from when the first input signal indicating startup is input until the channel allocated to the enable function starts up, and
second delay time information related to an elapsed time from when the second input signal indicating startup is input until the channel allocated to the additional enable function starts up.

2. The semiconductor device according to claim 1, wherein
the first input signal is an enable signal that takes a high level or a low level, and
the channel allocated to the enable function starts up at a timing when an elapsed time indicated by the first delay time information has elapsed after the enable signal is switched to a level indicating startup.

3. The semiconductor device according to claim 2, wherein
the second input signal is an additional enable signal that takes a high level or a low level, and
the channel allocated to the additional enable function starts up at a timing when an elapsed time indicated by the second delay time information has elapsed after the additional enable signal is switched to a level indicating startup.

4. The semiconductor device according to claim 3, wherein
the additional enable signal is inputtable to the first input part for a different function from the enable function and the additional enable function.

5. The semiconductor device according to claim 4, wherein
the different function is a synchronization function for synchronizing a switching frequency of the power supply circuit with an external clock, or a communication function with another semiconductor device.

6. The semiconductor device according to claim 2, further comprising a register, wherein
the second input signal is a serial communication signal, and
in a case where information indicating startup is written in the register by the serial communication signal, the channel allocated to the additional enable function starts up at a timing when an elapsed time indicated by the second delay time information has elapsed after the information is written.

7. The semiconductor device according to claim 1, wherein
the first delay time information has a step that lengthens as a setting time increases.

8. The semiconductor device according to claim 1, configured to be capable of setting:
third delay time information related to an elapsed time from when the first input signal indicating shutdown is input until the channel allocated to the enable function shuts down, and
fourth delay time information related to an elapsed time from when the second input signal indicating shutdown is input until the channel allocated to the additional enable function shuts down.

9. The semiconductor device according to claim 1, further comprising a first output part configured to output a reset signal, wherein
the semiconductor device is configured to be capable of setting:
allocation of the reset signal to the additional enable function, and
fifth delay time information related to an elapsed time from when the second input signal indicating startup is input until the reset signal transitions to a reset release state.

10. The semiconductor device according to claim 9, further comprising a second output part configured to output an additional reset signal, wherein
the semiconductor device is configured to be capable of setting:
allocation of the additional reset signal to the additional enable function, and
sixth delay time information related to an elapsed time from when the channel that starts up last among the channels allocated to the additional enable function completes startup until the additional reset signal transitions to a reset release state.

11. The semiconductor device according to claim 10, wherein
the additional reset signal is outputtable from the second output part for a different function from a power-on reset function.

12. A power supply system, comprising:
the semiconductor device according to claim 1; and
an external device configured to be supplied with an output voltage generated based on the power supply circuit.

13. The power supply system according to claim 12, wherein
the second input signal is inputtable from the external device to the semiconductor device.

14. The power supply system according to claim 13, wherein
the external device is a SoC.

15. The power supply system according to claim 12, further comprising a sequencer, wherein
the second input signal is inputtable from the sequencer to the semiconductor device.

16. A vehicle, comprising the power supply system according to claim 12.
